(19) United States
(12) Patent Application Publication
(10) Pub. No.: US 2025/0234621 A1
(43) Pub. Date: Jul. 17, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Changwoo Noh, Suwon-si (KR); Myunggil Kang, Suwon-si (KR)

(21) Appl. No.: 18/773,710

(22) Filed: Jul. 16, 2024

(30) Foreign Application Priority Data
Jan. 16, 2024 (KR) 10-2024-0006808

(51) Int. Cl. H01L 29/423; H01L 29/08; H01L 29/417; H01L 29/66

(52) U.S. Cl. CPC H10D 64/514; H10D 62/151; H10D 64/018; H10D 64/252

(57) ABSTRACT

A semiconductor device includes first semiconductor patterns and second semiconductor patterns alternately stacked one-by-one on an upper surface of a substrate, a gate electrode on an uppermost one of the first and second semiconductor patterns, the gate electrode extending in a first lateral direction, a first source/drain pattern and a second source/drain pattern spaced apart from each other, with the first and second semiconductor patterns therebetween, in a second lateral direction intersecting the first lateral direction, and a protective pattern between the gate electrode and the uppermost one of the first and second semiconductor patterns. The protective pattern is directly on sidewalls of the first and second semiconductor patterns in the first lateral direction.

### CROSS-REFERENCE TO RELATED APPLICATIONS

This application is based on and claims priority under 35 U.S.C. § 119 to Korean Patent Application No. 10-2024-0006808, filed on Jan. 16, 2024, in the Korean Intellectual Property Office, the disclosure of which is incorporated by reference herein in its entirety.

### BACKGROUND OF THE INVENTION

The inventive concepts relate to a semiconductor device and a method of manufacturing the same.

A semiconductor device may include an integrated circuit (IC) including not only metal oxide semiconductor field-effect transistors (MOSFETs) but also a passive element. The passive element may include a diode. As the sizes and design rules of semiconductor devices are gradually reduced, the downscaling of the MOSFETs and the passive element is also accelerating. With a reduction in the sizes of the MOSFETs and the passive element, operating characteristics of the semiconductor devices may deteriorate. Accordingly, research has been conducted on various methods of forming semiconductor devices with excellent performance, while overcoming the limitations caused by high integration of the semiconductor devices.

### SUMMARY OF THE INVENTION

The inventive concepts provide a semiconductor device with improved electrical properties.

The inventive concepts also provide a method of manufacturing a semiconductor device with improved electrical properties.

According to aspects of the inventive concepts, there is provided a semiconductor device including a substrate including a first region and a second region beside the first region, the first region having a first conductivity type and the second region having a second conductivity type different from the first conductivity type, first semiconductor patterns and second semiconductor patterns alternately stacked one-by-one on an upper surface of the substrate, the first semiconductor patterns including a different material from the second semiconductor patterns, a gate electrode on an uppermost one of the first and second semiconductor patterns, the gate electrode extending in a first lateral direction, a first source/drain pattern and a second source/drain pattern spaced apart from each other, with the first and second semiconductor patterns therebetween, in a second lateral direction intersecting the first lateral direction, the first source/drain pattern having the first conductivity type and the second source/drain pattern having the second conductivity type, and a protective pattern between the gate electrode and the uppermost one of the first and second semiconductor patterns, the protective pattern including a dielectric material, wherein the protective pattern is directly on sidewalls of the first and second semiconductor patterns in the first lateral direction.

According to aspects of the inventive concepts, there is provided a semiconductor device including a lower wiring layer including a lower insulating layer and a lower wiring in the lower insulating layer, first semiconductor patterns and second semiconductor patterns alternately stacked one-by-one on an upper surface of the lower wiring layer, the first semiconductor patterns including a different material from the second semiconductor patterns, a gate electrode on an uppermost one of the first and second semiconductor patterns, the gate electrode extending in a first lateral direction, a first source/drain pattern and a second source/drain pattern spaced apart from each other, with the first and second semiconductor patterns therebetween, in a second lateral direction intersecting the first lateral direction, the first source/drain pattern having a first conductivity type and the second source/drain pattern having a second conductivity type different from the first conductivity type, a protective pattern between the gate electrode and the uppermost one of the first and second semiconductor patterns, the protective pattern including a dielectric material, and a gate spacer on a sidewall of the gate electrode in the second lateral direction, wherein the protective pattern includes a first portion on the uppermost one of the first and second semiconductor patterns and a second portion extending along an inner sidewall of the gate spacer in a vertical direction.

According to aspects of the inventive concepts, there is provided a semiconductor device including a substrate including a first region and a second region beside the first region, the first region having a first conductivity type and the second region having a second conductivity type different from the first conductivity type, first semiconductor patterns and second semiconductor patterns alternately stacked one-by-one on an upper surface of the substrate, the first semiconductor patterns including a different material from the second semiconductor patterns, a gate electrode on an uppermost one of the first and second semiconductor patterns, the gate electrode extending in a first lateral direction, a gate spacer on a sidewall of the gate electrode in a second lateral direction intersecting the first lateral direction, a first source/drain pattern and a second source/drain pattern spaced apart from each other, with the first and second semiconductor patterns therebetween, in the second lateral direction, a protective pattern between the gate electrode and the uppermost one of the first and second semiconductor patterns, the protective pattern including a dielectric material, a gate capping pattern on an upper surface of the gate electrode, an interlayer insulating film on the gate capping pattern, and a metal layer on the interlayer insulating film, wherein the protective pattern is directly on sidewalls of the first and second semiconductor patterns in the first lateral direction.

### BRIEF DESCRIPTION OF THE DRAWINGS

Example embodiments will be more clearly understood from the following detailed description taken in conjunction with the accompanying drawings, in which:

FIG. 1 is a plan view of a semiconductor device according to some embodiments;

FIG. 2 is a cross-sectional view taken along line A-A′ of FIG. 1, according to some embodiments;

FIG. 3 is an enlarged view of region “M” of FIG. 2, according to some embodiments;

FIG. 4 is a cross-sectional view taken along line I-I′ of FIG. 3, according to some embodiments;

FIG. 5A is a cross-sectional view taken along line A-A′ of FIG. 1, according to some embodiments;

FIG. 5B is a cross-sectional view taken along line A-A′ of FIG. 1, according to some embodiments;

FIG. 6 is a cross-sectional view taken along line A-A′ of FIG. 1, according to some embodiments;

FIG. 7 is a cross-sectional view taken along line A-A′ of FIG. 1, according to some embodiments;

FIG. 8A is a cross-sectional view taken along line A-A′ of FIG. 1, according to some embodiments;

FIG. 8B is a cross-sectional view taken along line A-A′ of FIG. 1, according to some embodiments;

FIG. 9 is a cross-sectional view taken along line A-A′ of FIG. 1, according to some embodiments;

FIG. 10 is a cross-sectional view taken along line A-A′ of FIG. 1, according to some embodiments;

FIG. 11 is an enlarged view of region “N” of FIG. 10, according to some embodiments;

FIGS. 12A to 12I are cross-sectional views illustrating a method of manufacturing a semiconductor device, according to some embodiments; and

FIGS. 13A and 13B are cross-sectional views illustrating a method of manufacturing a semiconductor device, according to some embodiments.

### DETAILED DESCRIPTION

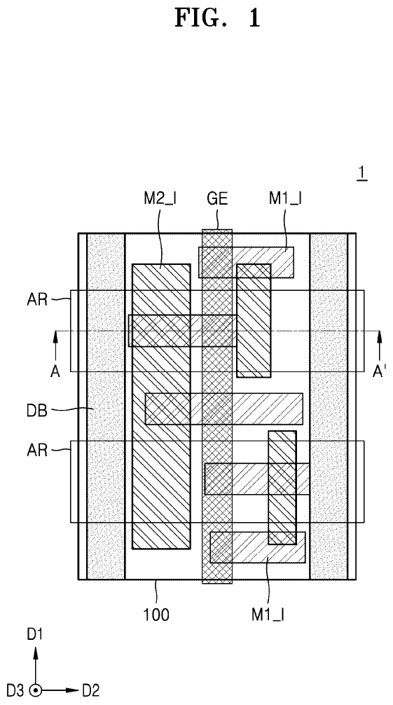

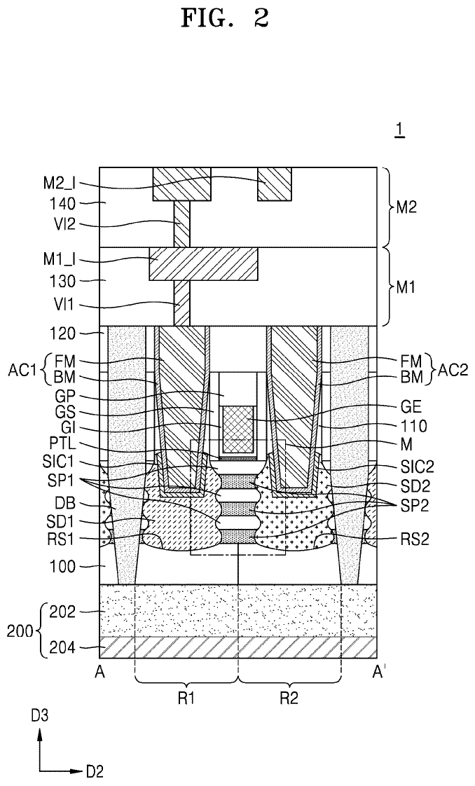

FIG. 1 is a plan view of a semiconductor device according to some embodiments. FIG. 2 is a cross-sectional view taken along line A-A′ of FIG. 1, according to some embodiments.

Referring to FIGS. 1 and 2, a semiconductor device 1 may include a substrate 100.

The substrate 100 may include a semiconductor substrate including silicon, germanium, or silicon-germanium. In some embodiments, the substrate 100 may include a compound semiconductor substrate. As an example, the substrate 100 may include a silicon substrate. As another example, the substrate 100 may include single crystalline silicon, germanium, or silicon-germanium.

When the substrate 100 includes single crystalline silicon, germanium, or silicon-germanium, the substrate 100 may have a (100) plane, a (110) plane, or a (111) plane as a main surface.

An active region AR may be defined by a trench (not shown) formed in an upper portion of the substrate 100. The active region AR may be provided in plural. The active region AR may extend in a second lateral direction D2. In the active region AR, the substrate 100 may include a portion protruding in a vertical direction D3.

As used herein, a direction parallel to an upper surface of the substrate 100 may be defined as a first lateral direction D1, a direction that is parallel to the upper surface of the substrate 100 and intersects with the first lateral direction D1 may be defined as the second lateral direction D2, and a direction perpendicular to the upper surface of the substrate 100 may be defined as the vertical direction D3.

The active region AR may include a first region R1 and a second region R2 between a pair of isolation structures DB. The first region R1 and the second region R2 may be adjacent to each other in the second lateral direction D2. The second region R2 may be beside the first region R1.

In the first region R1, the substrate 100 may include impurities of a first conductivity type (e.g., n-type). In the second region R2, the substrate 100 may include impurities of a second conductivity type (e.g., p-type). For example, the first region R1 may have the first conductivity type, and the second region R2 may have the second conductivity type. The first conductivity type may be different from the second conductivity type.

The first region R1 and the second region R2 may form a PN junction. Thus, the first region R1 and the second region R2 may function as diodes.

In the active region AR, first semiconductor patterns SP1 and second semiconductor patterns SP2 may be provided on the substrate 100. The first semiconductor patterns SP1 and the second semiconductor patterns SP2 may be alternately stacked one-by-one.

The first semiconductor patterns SP1 may be spaced apart from each other in the vertical direction D3. The second semiconductor patterns SP2 may be spaced apart from each other in the vertical direction D3.

The first semiconductor patterns SP1 may include one of silicon, germanium, or silicon-germanium, and the second semiconductor patterns SP2 may include another one of silicon, germanium, or silicon-germanium.

The second semiconductor patterns SP2 may include a material having etch selectivity with respect to the first semiconductor patterns SP1. For example, the first semiconductor patterns SP1 may include silicon, and the second semiconductor patterns SP2 may include silicon-germanium. Each of the second semiconductor patterns SP2 may have a germanium (Ge) concentration of about 10 atomic percent (at %) to about 30 at %.

In the first region R1, a first source/drain pattern SD1 may be provided on the substrate 100. A first recess RS1 may be formed in an upper portion of the substrate 100. The first recess RS1 may pass (i.e., extend) through the first semiconductor patterns SP1 and the second semiconductor patterns SP2. The first source/drain pattern SD1 may be provided inside the first recess RS1. The first source/drain pattern SD1 may include impurities of the first conductivity type (e.g., n type). For example, the first source/drain pattern SD1 may have the first conductivity type.

In the second region R2, a second source/drain pattern SD2 may be provided on the substrate 100. A second recess RS2 may be formed in an upper portion of the substrate 100. The second recess RS2 may pass through the first semiconductor patterns SP1 and the second semiconductor patterns SP2. The second source/drain pattern SD2 may be provided inside the second recess RS2. The second source/drain pattern SD2 may include impurities of a second conductivity type (e.g., p type). For example, the second source/drain pattern SD2 may have the second conductivity type.

The first source/drain pattern SD1 and the second source/drain pattern SD2 may be adjacent to each other in the second lateral direction D2. The first semiconductor patterns SP1 and the second semiconductor patterns SP2 may be between the first source/drain pattern SD1 and the second source/drain pattern SD2. The first and second semiconductor patterns SP1 and SP2, which are stacked, may connect the first source/drain pattern SD1 and the second source/drain pattern SD2 to each other. As used herein, “an element A connected to an element B” (or similar language) means that the element A is physically and/or electrically connected to the element B.

The first source/drain pattern SD1 may be on (e.g., may cover) sidewalls and a bottom surface of the first recess RS1. The second source/drain pattern SD2 may be on (e.g., may cover) sidewalls and a bottom surface of the second recess RS2.

The first source/drain pattern SD1 and the second source/drain pattern SD2 may be formed using a selective epitaxial growth (SEG) process.

In some embodiments, an upper surface of each of the first and second source/drain patterns SD1 and SD2 may be higher than an upper surface of an uppermost one of the first and second semiconductor patterns SP1 and SP2.

In other embodiments, the upper surface of at least one of the first and second source/drain patterns SD1 and SD2 may be substantially at the same level as (e.g., coplanar with) the upper surface of the uppermost one of the first and second semiconductor patterns SP1 and SP2.

A sidewall of each of the first and second source/drain patterns SD1 and SD2 may have an uneven, embossed shape. In other words, the sidewall of each of the first and second source/drain patterns SD1 and SD2 may have a wavy profile. The sidewall of each of the first and second source/drain patterns SD1 and SD2 may protrude toward each of the second semiconductor patterns SP2 (e.g., in the second lateral direction D2).

Gate electrodes GE may be provided across the first and second semiconductor patterns SP1 and SP2 and may extend in the first lateral direction D1. The gate electrode GE may overlap the first and second semiconductor patterns SP1 and SP2 in a vertical direction (i.e., the vertical direction D3). As used herein, “an element A overlaps an element B in a direction X” (or similar language) means that there is at least one straight line that extends in the direction X and intersects both the elements A and B.

The gate electrode GE may be on the upper surface of the uppermost one of the first and second semiconductor patterns SP1 and SP2.

The gate electrode GE may include a first metal pattern and a second metal pattern on the first metal pattern. The first metal pattern may include a work-function metal. For example, the first metal pattern may include a metal nitride film. For example, the first metal pattern may include nitrogen (N) and at least one selected from the group consisting of titanium (Ti), tantalum (Ta), aluminum (Al), tungsten (W), and molybdenum (Mo). Furthermore, the first metal pattern may further include carbon (C). The first metal pattern may include a plurality of work-function metal films, which are stacked.

The second metal pattern may include a metal having a lower resistance than the first metal pattern. For example, the second metal pattern may include at least one metal selected from the group consisting of tungsten (W), aluminum (Al), titanium (Ti), and tantalum (Ta).

A protective pattern PTL may be between the uppermost one of the first and second semiconductor patterns SP1 and SP2 and the gate electrode GE (e.g., in the vertical direction D3). The protective pattern PTL may be on (e.g., may cover) at least a portion of the upper surface of the uppermost one of the first and second semiconductor patterns SP1 and SP2.

The protective pattern PTL may be spaced apart from the gate electrode GE with a gate insulating film GI therebetween. Specifically, in FIG. 2, the protective pattern PTL may be spaced apart from the gate electrode GE in the vertical direction D3 with the gate insulating film GI therebetween.

The protective pattern PTL may not be between the uppermost one of the first and second semiconductor patterns SP1 and SP2 and the gate spacer GS. That is, the protective pattern PTL may not overlap the gate spacer GS in the vertical direction D3.

The protective pattern PTL may include a low-k dielectric material. For example, the protective pattern PTL may include a silicon oxide film, a silicon oxynitride film, or a combination thereof.

A pair of gate spacers GS may be respectively on both (i.e., opposing) sidewalls of the gate electrode GE. The gate spacers GS may extend along the gate electrode GE in the first lateral direction D1.

Upper surfaces of the gate spacers GS may be at a higher level than an upper surface of the gate electrode GE. The upper surfaces of the gate spacers GS may be coplanar with the upper surface of the first interlayer insulating film 110. As used herein, the term “level” refers to a height or distance in the vertical direction D3 from a lower surface of the substrate 100.

In some embodiments, the gate spacers GS may include at least one of silicon carbonitride (SiCN), silicon carbon oxynitride (SiCON), or silicon nitride (SiN). In other embodiments, the gate spacers GS may include a multilayered film including at least two of SiCN, SiCON, and SiN.

A gate capping pattern GP may be provided on the gate electrode GE. The gate capping pattern GP may extend along the gate electrode GE in the first lateral direction D1.

The gate capping pattern GP may include a material having etch selectivity with respect to the first and second interlayer insulating films 110 and 120. Specifically, the gate capping pattern GP may include at least one of silicon oxynitride (SiON), SiCN, SiCON, or SiN.

The gate insulating film GI may be between the gate electrode GE and the protective pattern PTL and between the gate electrode GE and the gate spacer GS. The gate insulating film GI may be on (e.g., may cover) an upper surface of the protective pattern PTL. The gate insulating film GI may be on (e.g., may cover) a side surface of the gate electrode GE.

A first interlayer insulating film 110 may be provided on the substrate 100. The first interlayer insulating film 110 may be on (e.g., may cover) the gate spacers GS and the first and second source/drain patterns SD1 and SD2.

An upper surface of the first interlayer insulating film 110 may form a substantially planar surface with an upper surface of the gate capping pattern GP and the upper surface of the gate spacer GS.

A second interlayer insulating film 120 on (e.g., covering) the gate capping pattern GP may be on the first interlayer insulating film 110. A third interlayer insulating film 130 may be provided on the second interlayer insulating film 120. A fourth interlayer insulating film 140 may be provided on the third interlayer insulating film 130. In some embodiments, each of the first to fourth interlayer insulating films 110-140 may include a silicon oxide film.

A pair of isolation structures DB may face each other in the second lateral direction D2 with the first and second source/drain patterns SD1 and SD2 therebetween. The isolation structure DB may extend parallel to the gate electrodes GE in the first lateral direction D1.

The isolation structure DB may pass through the first and second interlayer insulating films 110 and 120 and extend into the substrate 100. The isolation structure DB may electrically isolate one active region AR from another active region AR adjacent thereto.

A first active contact AC1 may pass through the first and second interlayer insulating films 110 and 120 and be electrically connected to the first source/drain pattern SD1. A second active contact AC2 may pass through the first and second interlayer insulating films 110 and 120 and be electrically connected to the second source/drain pattern SD2.

The first and second active contacts AC1 and AC2 may be respectively provided on both sides of the gate electrode GE. In a view from above, each of the first and second active contacts AC1 and AC2 may have a bar shape extending in the first lateral direction D1.

The first and second active contacts AC1 and AC2 may be self-aligned contacts. In other words, the first and second active contacts AC1 and AC2 may be formed in a self-aligned manner by using the gate capping pattern GP and the gate spacer GS. For example, the first and second active contacts AC1 and AC2 may be on (e.g., may cover) at least a portion of a sidewall of the gate spacer GS.

Each of the first and second active contacts AC1 and AC2 may include a conductive pattern FM and a barrier pattern BM surrounding the conductive pattern FM. It will be understood that “an element A surrounds an element B” (or similar language) as used herein means that the element A is at least partially around the element B but does not necessarily mean that the element A completely encloses the element B.

For example, the conductive pattern FM may include at least one metal of aluminum, copper, tungsten, molybdenum, or cobalt.

The barrier pattern BM may be on (e.g., may cover) sidewalls and a bottom surface of the conductive pattern FM. The barrier pattern BM may include a metal film/metal nitride film.

The metal film may include at least one of titanium, tantalum, tungsten, nickel, cobalt, or platinum.

The metal nitride film may include at least one of a titanium nitride (TiN) film, a tantalum nitride (TaN) film, a tungsten nitride (WN) film, a nickel nitride (NiN) film, a cobalt nitride (CoN) film, or a platinum nitride (PtN) film.

A first metal-semiconductor compound layer SIC1 may be between the first active contact AC1 and the first source/drain pattern SD1. A second metal-semiconductor compound layer SIC2 may be between the second active contact AC2 and the second source/drain pattern SD2.

The first active contact AC1 may be electrically connected to the first source/drain pattern SD1 through the first metal-semiconductor compound layer SIC1. The second active contact AC2 may be electrically connected to the second source/drain pattern SD2 through the second metal-semiconductor compound layer SIC2.

For example, each of the first and second metal-semiconductor compound layers SIC1 and SIC2 may include at least one of titanium-silicide, tantalum-silicide, tungsten-silicide, nickel-silicide, or cobalt-silicide.

A first metal layer M1 may be provided in the third interlayer insulating film 130. For example, the first metal layer M1 may include first wirings M1_I. The first wirings M1_I of the first metal layer M1 may extend parallel to each other in the second lateral direction D2.

The first metal layer M1 may further include first vias VI1. The first vias VI1 may be respectively provided under the first wirings M1_I of the first metal layer M1. The first and second active contacts AC1 and AC2 may be electrically connected to a wiring of the first metal layer M1 through the first via VI1. Although not shown, the gate electrode GE may be electrically connected to the first wiring M1_I of the first metal layer M1 through the first via VI1.

The first wiring M1_I of the first metal layer M1 and the first via VI1 located thereunder may be formed using separate processes. In other words, each of the first wiring M1_I of the first metal layer M1 and the first via VI1 may be formed using a single damascene process. The semiconductor device 1 according to some embodiments may be formed using a sub-20-nm process.

A second metal layer M2 may be provided in the fourth interlayer insulating film 140. The second metal layer M2 may include a plurality of second wirings M2_I. Each of the second wirings M2_I of the second metal layer M2 may have a line shape or bar shape extending in the first lateral direction D1. In other words, the second wirings M2_I may extend parallel to each other in the first lateral direction D1.

The second metal layer M2 may further include second vias VI2 respectively provided under the second wirings M2_I. The first wiring M1_I of the first metal layer M1 may be electrically connected to the second wiring M2_I of the second metal layer M2 through the second via VI2. In some embodiments, the second wiring M2_I of the second metal layer M2 and the second via VI2 located under the second wiring M2_I may be formed together using a dual damascene process.

The first wiring M1_I of the first metal layer M1 and the second wiring M2_I of the second metal layer M2 may include the same conductive material as each other or different conductive materials from each other. For example, the first wiring M1_I of the first metal layer M1 and the second wiring M2_I of the second metal layer M2 may include at least one metal material selected from aluminum, copper, tungsten, molybdenum, ruthenium, and cobalt.

Although not shown, metal layers may be further stacked on the fourth interlayer insulating film 140.

A lower wiring layer 200 may be under the substrate 100. The lower wiring layer 200 may include a lower insulating layer 202 and a lower wiring 204.

The lower insulating layer 202 may include a single layer or a plurality of layers. When the lower insulating layer 202 includes the plurality of layers, the plurality of layers may include the same material or different materials.

The lower insulating layer 202 may include a low-k dielectric material. For example, the lower insulating layer 202 may include a silicon oxide film, a silicon nitride film, or a silicon oxynitride film. The lower insulating layer 202 may be on (e.g., may cover) a lower surface of the substrate 100.

The lower wiring 204 may be in the lower insulating layer 202. Although the lower wiring 204 is illustrated as extending in the second lateral direction D2 in FIG. 2, the lower wiring 204 may extend in the first lateral direction D1. Although the lower wiring 204 is illustrated as including only one layer in FIG. 2, the lower wiring 204 may include a plurality of layers.

The lower wiring 204 may include at least one metal of aluminum, copper, tungsten, molybdenum, or cobalt.

In some embodiments, the lower wiring 204 may be electrically connected to the first wiring M1_I and/or the second wiring M2_I.

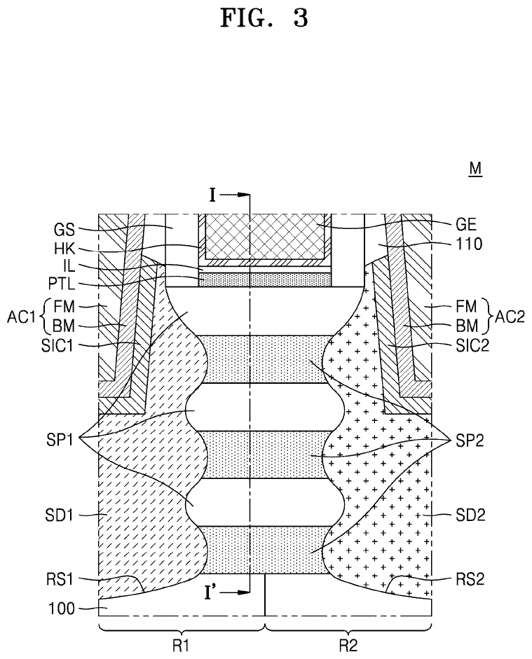

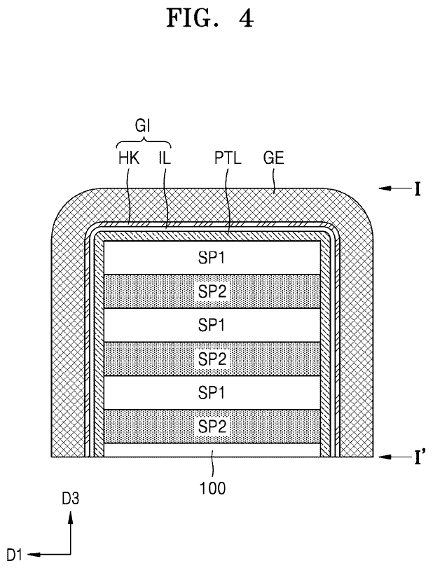

FIG. 3 is an enlarged view of region M of FIG. 2, according to some embodiments. FIG. 4 is a cross-sectional view taken along line I-I′ of FIG. 3, according to some embodiments.

Referring to FIG. 3, a gate insulating film GI may include an interfacial film IL and a high-k dielectric film HK. The interfacial film IL may be directly on (e.g., may directly cover) a top surface of a protective pattern PTL. For example, the interfacial film IL may be in contact with the protective pattern PTL. The interfacial film IL may be between the protective pattern PTL and the high-k dielectric film HK (e.g., in the vertical direction D3). For example, the high-k dielectric film HK may be spaced apart from the protective pattern PTL with the interfacial film IL therebetween in the vertical direction D3.

The high-k dielectric film HK may be between the interfacial film IL and a gate electrode GE (e.g., in the vertical direction D3). The high-k dielectric film HK may be directly on (e.g., may directly cover) a surface of the gate electrode GE. For example, the high-k dielectric film HK may be in contact with the gate electrode GE. The high-k dielectric film HK may be directly on (e.g., may directly cover) a top surface of the interfacial film IL. The high-k dielectric film HK may extend along a sidewall of the gate electrode GE in the vertical direction D3.

On an uppermost one of the first and second semiconductor patterns SP1 and SP2, the high-k dielectric film HK may be spaced apart from the protective pattern PTL in the vertical direction D3.

The interfacial film IL may include a silicon oxide film or a silicon oxynitride film. The high-k dielectric film HK may include a high-k dielectric material having a higher dielectric constant than the silicon oxide film. In some embodiments, the high-k dielectric film HK may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some embodiments, the gate insulating film GI may include one ferroelectric material film. In other embodiments, the gate insulating film GI may include a plurality of ferroelectric material films, which are spaced apart from each other. The gate insulating film GI may have a stack film structure in which a plurality of ferroelectric material films and a plurality of paraelectric material films are alternately stacked.

Referring to FIG. 4, the protective pattern PTL may extend in a first lateral direction D1. The protective pattern PTL may extend along sidewalls of the first and second semiconductor patterns SP1 and SP2 in the first lateral direction D1 and may be directly on (e.g., may directly cover) the sidewalls of the first and second semiconductor patterns SP1 and SP2 in the first lateral direction D1. For example, the protective pattern PTL may be directly on opposing sidewalls of the first and second semiconductor patterns SP1 and SP2 in the first lateral direction D1.

The interfacial film IL of the gate insulating film GI may extend in the first lateral direction D1. The interfacial film IL may extend along a sidewall of the protective pattern PTL in the first lateral direction D1 and may be directly on (e.g., may directly cover) the sidewall of the protective pattern PTL in the first lateral direction D1. For example, the interfacial film IL may be directly on opposing sidewalls of the protective pattern PTL in the first lateral direction D1.

In some embodiments, the protective pattern PTL and the interfacial film IL may include the same material as each other. In this case, a boundary between the protective pattern PTL and the interfacial film IL may not be observed.

The high-k dielectric film HK of the gate insulating film GI may extend in the first lateral direction D1. The high-k dielectric film HK may extend along a sidewall of the interfacial film IL in the first lateral direction D1 and may be directly on (e.g., may directly cover) the sidewall of the interfacial film IL in the first lateral direction D1. For example, the high-k dielectric film HK may be directly on opposing sidewalls of the interfacial film IL in the first lateral direction D1.

On the sidewalls of the first and second semiconductor patterns SP1 and SP2 in the first lateral direction D1, the high-k dielectric film HK may be spaced apart from the protective pattern PTL in the first lateral direction D1 (e.g., with the interfacial film IL therebetween).

When the protective pattern PTL is omitted, the sidewalls of the first and second semiconductor patterns SP1 and SP2 in the first lateral direction D1 may be exposed during the manufacture of the semiconductor device 1. In this case, the second semiconductor patterns SP2 may be removed by using a wet etching process, and spaces where the second semiconductor patterns SP2 were removed may be filled with a material of the gate electrode GE.

When the spaces where the second semiconductor patterns SP2 were removed are filled by the material of the gate electrode GE, a distance between the gate electrode GE and the substrate 100 may be reduced. When the distance between the gate electrode GE and the substrate 100 is reduced, current leaking from a first region R1 and a second region R2 of the substrate 100 to the gate electrode GE may increase. In this case, the functions of diodes performed by the first region R1 and the second region R2 may deteriorate. As a result, the electrical properties and reliability of the semiconductor device 1 may degrade.

According to the inventive concepts, the semiconductor device 1 may include the first and second semiconductor patterns SP1 and SP2, which are alternately stacked one-by-one on the substrate 100 including the first region R1 and the second region R2. A gate electrode GE may be on the uppermost one of the first and second semiconductor patterns SP1 and SP2. The protective pattern PTL may be between the gate electrode GE and the uppermost one of the first and second semiconductor patterns SP1 and SP2.

Moreover, the protective pattern PTL may be on (e.g., may cover) the sidewalls of the first and second semiconductor patterns SP1 and SP2 in the first lateral direction D1. As a result, the second semiconductor patterns SP2 may not be removed during the manufacture of the semiconductor device 1. Accordingly, the distance between the gate electrode GE and the substrate 100 may increase, and thus, current leaking from the first region R1 and the second region R2 to the gate electrode GE may be reduced. For the above-described reasons, the electrical properties and reliability of the semiconductor device 1 may improve.

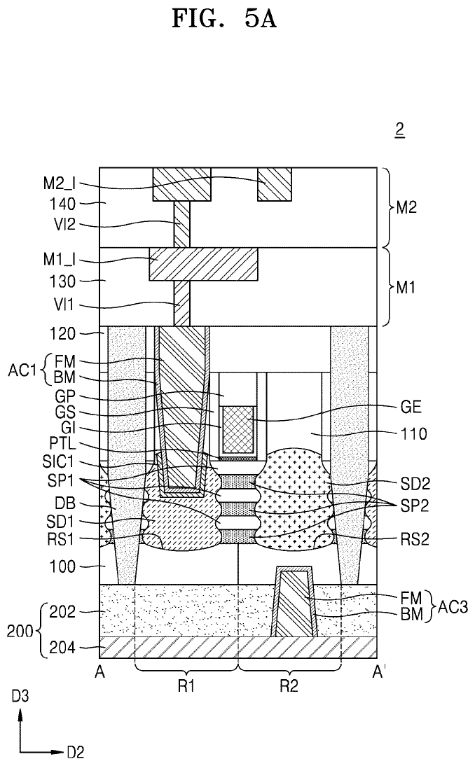

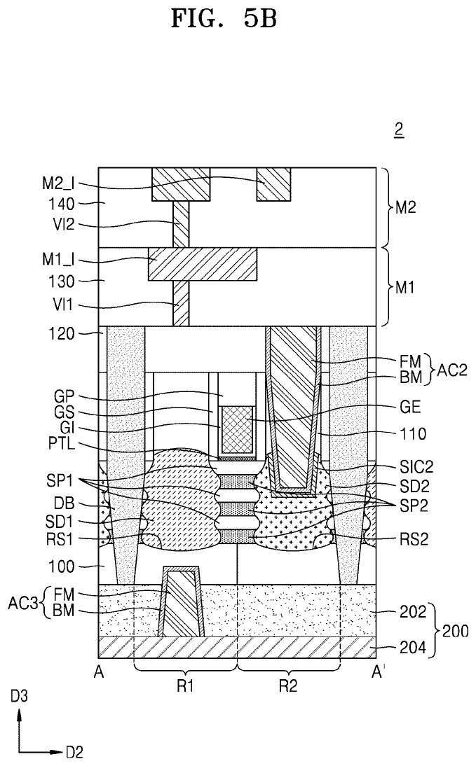

FIG. 5A is a cross-sectional view taken along line A-A′ of FIG. 1, according to some embodiments. FIG. 5B is a cross-sectional view taken along line A-A′ of FIG. 1, according to some embodiments. The description of each component may be the same as or similar to that given with reference to FIGS. 1 to 4 except for those described below. Thus, repeated descriptions are briefly mentioned or excluded, and only differences are described in detail.

Referring to FIGS. 5A and 5B, a semiconductor device 2 may further include a third active contact AC3. Any one of the first active contact AC1 or the second active contact AC2 included in the semiconductor device 1 of FIG. 2 may be omitted.

The third active contact AC3 may be in direct contact with a lower wiring 204. Alternatively, the third active contact AC3 may be electrically connected to the lower wiring 204 but not in direct contact with the lower wiring 204. The third active contact AC3 may pass through a lower insulating layer 202 and extend into a substrate 100 in a vertical direction D3. At least a portion of the third active contact AC3 may be surrounded by the substrate 100.

As shown in FIG. 5A, when the second active contact AC2 is omitted, the third active contact AC3 may extend to the second region R2 of the substrate 100 in the vertical direction D3. In this case, the third active contact AC3 may be electrically connected to the second region R2 of the substrate 100.

As shown in FIG. 5B, when the first active contact AC1 is omitted, the third active contact AC3 may extend to a first region R1 of the substrate 100 in the vertical direction D3. In this case, the third active contact AC3 may be electrically connected to the first region R1 of the substrate 100.

The third active contact AC3 may include a conductive pattern FM and a barrier pattern BM. The barrier pattern BM may be on (e.g., may cover) a surface of the conductive pattern FM. The conductive pattern FM and the barrier pattern BM may include the same material as that described with reference to FIGS. 1 and 2.

When one of the first and second active contacts AC1 and AC2 is omitted and the third active contact AC3 is arranged, a degree of freedom for arrangement of a first wiring M1_I and a second wiring M2_I may increase. Accordingly, the integration density of the semiconductor device 2 may increase.

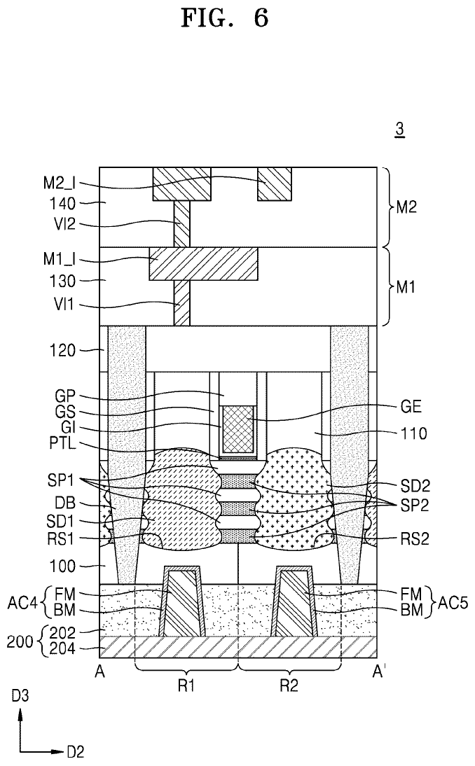

FIG. 6 is a cross-sectional view taken along line A-A′ of FIG. 1, according to some embodiments. The description of each component may be the same as or similar to that given with reference to FIGS. 1 to 4 except for those described below. Thus, repeated descriptions are briefly mentioned or excluded, and only differences are described in detail.

Referring to FIG. 6, a semiconductor device 3 may further include a fourth active contact AC4 and a fifth active contact AC5. However, both the first active contact AC1 and the second active contact AC2 included in the semiconductor device 1 of FIG. 2 may be omitted.

The fourth active contact AC4 and the fifth active contact AC5 may be directly connected to a lower wiring 204. Alternatively, the fourth active contact AC4 and the fifth active contact AC5 may be electrically connected to the lower wiring 204 but not in direct contact with the lower wiring 204. The fourth active contact AC4 and the fifth active contact AC5 may pass through a lower insulating layer 202 and extend into a substrate 100 in a vertical direction D3. At least a portion of the fourth active contact AC4 and at least a portion of the fifth active contact AC5 may be surrounded by the substrate 100.

The fourth active contact AC4 may extend to a first region R1 of the substrate 100 in the vertical direction D3. The fourth active contact AC4 may be electrically connected to the first region R1 of the substrate 100.

The fifth active contact AC5 may extend to a second region R2 of the substrate 100 in the vertical direction D3. The fifth active contact AC5 may be electrically connected to the second region R2 of the substrate 100.

Each of the fourth and fifth active contacts AC4 and AC5 may include a conductive pattern FM and a barrier pattern BM. The barrier pattern BM may be on (e.g., may cover) a surface of the conductive pattern FM. The conductive pattern FM and the barrier pattern BM may include the same material as that described with reference to FIGS. 1 and 2.

When the first and second active contacts AC1 and AC2 are omitted and the fourth and fifth active contacts AC4 and AC5 are arranged, a degree of freedom for arrangement of a first wiring M1_I and a second wiring M2_I may increase. Accordingly, the integration density of the semiconductor device 3 may increase.

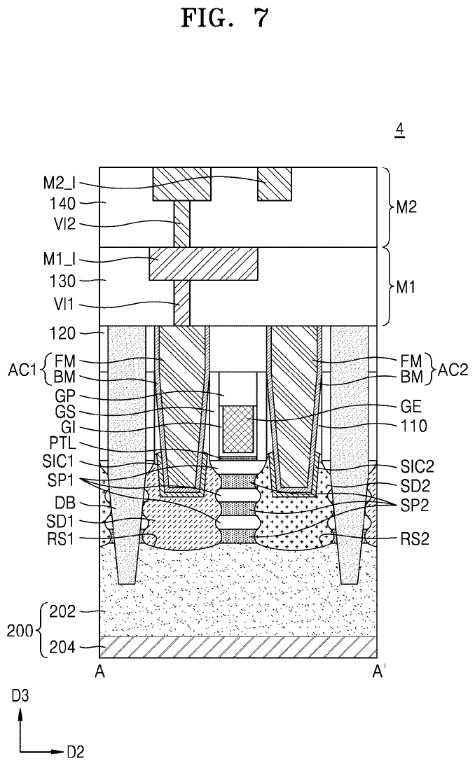

FIG. 7 is a cross-sectional view taken along line A-A′ of FIG. 1, according to some embodiments. The description of each component may be the same as or similar to that given with reference to FIGS. 1 to 4 except for those described below. Thus, repeated descriptions are briefly mentioned or excluded, and only differences are described in detail.

Referring to FIG. 7, a semiconductor device 4 may include most of the components included in the semiconductor device 1 of FIG. 2. However, in the semiconductor device 4, the substrate 100 included in the semiconductor device 1 of FIG. 2 may be omitted.

A space where the substrate 100 is omitted may be entirely filled by a lower insulating layer 202. The lower insulating layer 202 may be in direct contact with a lowermost one of first and second semiconductor patterns SP1 and SP2, a first source/drain pattern SD1, and a second source/drain pattern SD2.

Impurities of a first conductivity type in the first source/drain pattern SD1 may diffuse into the first and second semiconductor patterns SD1 and SD2. Impurities of a second conductivity type in the second source/drain pattern SD2 may diffuse into the first and second semiconductor patterns SD1 and SD2. As a result, the first source/drain pattern SD1 and the second source/drain pattern SD2 may form a PN junction. Accordingly, the first source/drain pattern SD1 and the second source/drain pattern SD2 may constitute a diode.

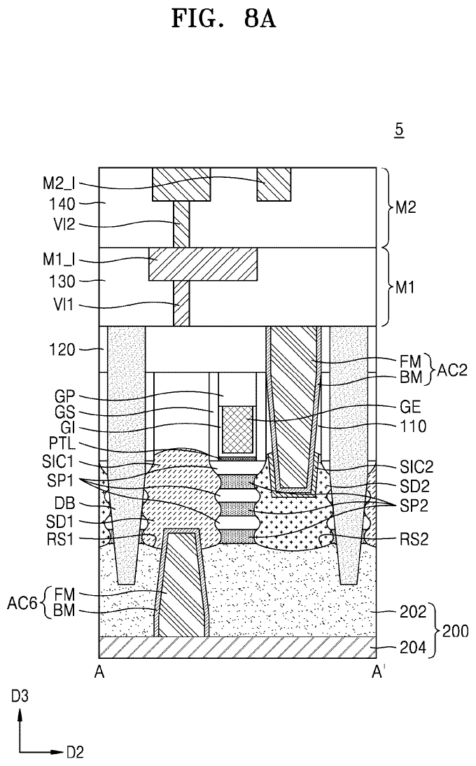

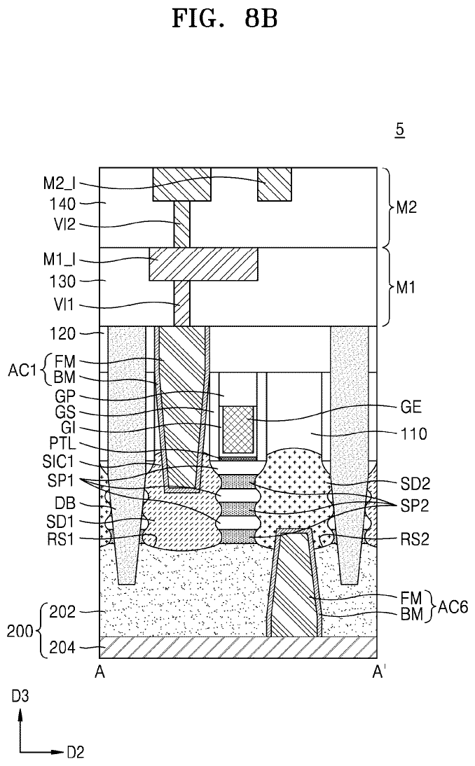

FIG. 8A is a cross-sectional view taken along line A-A′ of FIG. 1, according to some embodiments. FIG. 8B is a cross-sectional view taken along line A-A′ of FIG. 1, according to some embodiments. The description of each component may be the same as or similar to that given with reference to FIG. 7 except for those described below. Thus, repeated descriptions are briefly mentioned or excluded, and only differences are described in detail.

Referring to FIGS. 8A and 8B, a semiconductor device 5 may include most of the components included in the semiconductor device 4 of FIG. 7. However, in the semiconductor device 5, any one of the first active contact AC1 or the second active contact AC2 included in the semiconductor device 4 of FIG. 7 may be omitted.

The semiconductor device 5 may further include a sixth active contact AC6.

The sixth active contact AC6 may be directly connected to a lower wiring 204. Alternatively, the sixth active contact AC6 may be electrically connected to the lower wiring 204 but not in direct contact with the lower wiring 204. The sixth active contact AC6 may pass through a lower insulating layer 202 and extend into a first source/drain pattern SD1 or a second source/drain pattern SD2 in a vertical direction D3. At least a portion of the sixth active contact AC6 may be surrounded by the first source/drain pattern SD1 or the second source/drain pattern SD2.

As shown in FIG. 8A, when the first active contact AC1 is omitted, the sixth active contact AC6 may extend to the first source/drain pattern SD1 in the vertical direction D3. In this case, the sixth active contact AC6 may be electrically connected to the first source/drain pattern SD1.

As shown in FIG. 8B, when the second active contact AC2 is omitted, the sixth active contact AC6 may extend to the second source/drain pattern SD2 in the vertical direction D3. In this case, the sixth active contact AC6 may be electrically connected to the second source/drain pattern SD2.

The sixth active contact AC6 may include a conductive pattern FM and a barrier pattern BM. The barrier pattern BM may be on (e.g., may cover) a surface of the conductive pattern FM. The conductive pattern FM and the barrier pattern BM may include the same material as that described with reference to FIGS. 1 and 2.

When one of the first and second active contacts AC1 and AC2 is omitted and the sixth active contact AC6 is arranged, a degree of freedom for arrangement of a first wiring M1_I and a second wiring M2_I may increase. Accordingly, the integration density of the semiconductor device 5 may increase.

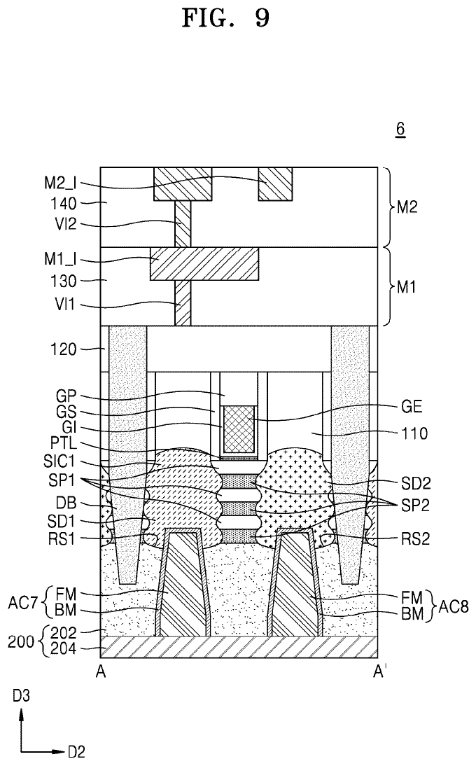

FIG. 9 is a cross-sectional view taken along line A-A′ of FIG. 1, according to some embodiments. The description of each component may be the same as or similar to that given with reference to FIG. 7 except for those described below. Thus, repeated descriptions are briefly mentioned or excluded, and only differences are described in detail.

A semiconductor device 6 may further include a seventh active contact AC7 and an eighth active contact AC8. However, both the first active contact AC1 and the second active contact AC2 included in the semiconductor device 4 of FIG. 7 may be omitted.

The seventh active contact AC7 and the eighth active contact AC8 may be directly connected to a lower wiring 204. Alternatively, the seventh active contact AC7 and the eighth active contact AC8 may be electrically connected to the lower wiring 204 but not in direct contact with the lower wiring 204. The seventh active contact AC7 may pass through a lower insulating layer 202 and extend into a first source/drain pattern SD1 in a vertical direction D3. The eighth active contact AC8 may pass through the lower insulating layer 202 and extend into a second source/drain pattern SD2 in the vertical direction D3. At least a portion of the seventh active contact AC7 may be surrounded by the first source/drain pattern SD1. At least a portion of the eighth active contact AC8 may be surrounded by the second source/drain pattern SD2.

The seventh active contact AC7 may be electrically connected to the first source/drain pattern SD1. The eighth active contact AC8 may be electrically connected to the second source/drain pattern SD2.

Each of the seventh and eighth active contacts AC7 and AC8 may include a conductive pattern FM and a barrier pattern BM. The barrier pattern BM may be on (e.g., may cover) a surface of the conductive pattern FM. The conductive pattern FM and the barrier pattern BM may include the same material as that described with reference to FIGS. 1 and 2.

When the first and second active contacts AC1 and AC2 are omitted and the seventh and eighth active contacts AC7 and AC8 are arranged, a degree of freedom for arrangement of a first wiring M1_I and a second wiring M2_I may increase. Accordingly, the integration density of the semiconductor device 6 may improve.

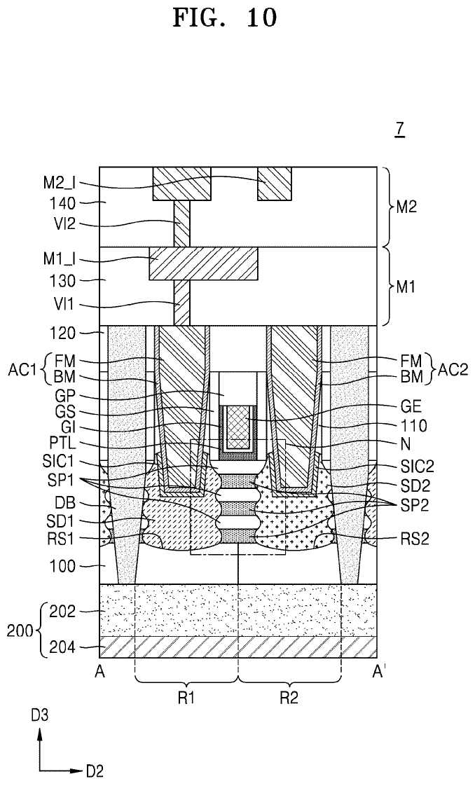

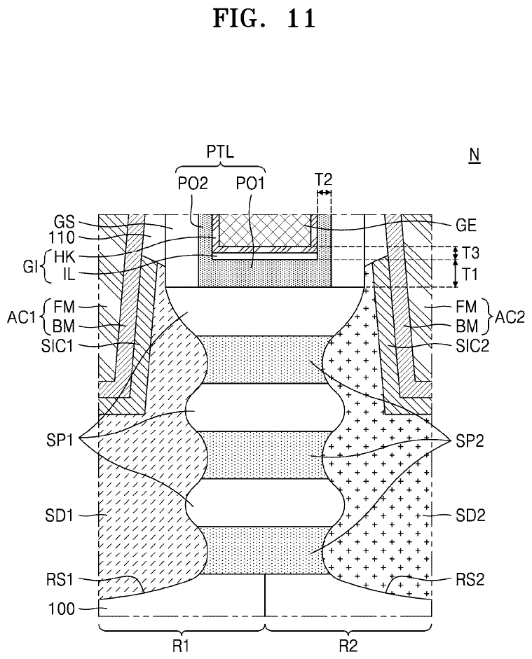

FIG. 10 is a cross-sectional view taken along line A-A′ of FIG. 1, according to some embodiments. FIG. 11 is an enlarged view of region N of FIG. 10, according to some embodiments. The description of each component may be the same as or similar to that given with reference to FIGS. 1 to 4 except for those described below. Thus, repeated descriptions are briefly mentioned or excluded, and only differences are described in detail.

Referring to FIGS. 10 and 11, a protective pattern PTL of a semiconductor device 7 may include a first portion PO1 and a second portion PO2 directly connected to the first portion PO1.

The first portion PO1 of the protective pattern PTL may be a portion directly contacting an uppermost one of the first and second semiconductor patterns SP1 and SP2. The first portion PO1 may include a first thickness T1. The first thickness T1 may be a thickness of the first portion PO1 in a vertical direction D3. Similar to the semiconductor device 1 of FIG. 4, the first portion PO1 may extend onto sidewalls of the first and second semiconductor patterns SP1 and SP2 in a first lateral direction D1. The first portion PO1 may be on (e.g., may cover) the sidewalls of the first and second semiconductor patterns SP1 and SP2 in the first lateral direction D1. For example, the first portion PO1 may be on opposing sidewalls of the first and second semiconductor patterns SP1 and SP2 in the first lateral direction D1.

An interfacial film IL of a gate insulating film GI may be on (e.g., may cover) an upper surface of the first portion PO1 and sidewalls of the first portion PO1 in the first lateral direction D1. For example, the interfacial film IL may be on an upper surface of the first portion PO1 and may be on opposing sidewalls of the first portion PO1 in the first lateral direction D1.

The second portion PO2 of the protective pattern PTL may be a portion extending from the first portion PO1 along an inner sidewall of the gate spacer GS in the vertical direction D3. The second portion PO2 of the protective pattern PTL may be directly on (e.g., may directly cover) the interfacial film IL and a sidewall of a high-k dielectric film HK in a second lateral direction D2. For example, the second portion PO2 of the protective pattern PTL may be directly on the interfacial film IL and may be directly on opposing sidewalls of the high-k dielectric film HK in the second lateral direction D2.

The high-k dielectric film HK may be spaced apart from the gate spacer GS in the second lateral direction D2 with the protective pattern PTL therebetween. Specifically, the high-k dielectric film HK may be spaced apart from the gate spacer GS in the second lateral direction D2 with the second portion PO2 of the protective pattern PTL therebetween. For example, the high-k dielectric film HK may be directly on an inner sidewall of the second portion PO2 of the protective pattern PTL.

The second portion PO2 of the protective pattern PTL may have a second thickness T2. The second thickness T2 may be a thickness of the second portion PO2 in the second lateral direction D2. The first thickness T1 may be greater than the second thickness T2. In other words, the second thickness T2 may be less than the first thickness T1.

A portion of the gate insulating film GI, which is in direct contact with the first portion PO1 of the protective pattern PTL, may have a third thickness T3. The third thickness T3 may be less than each of the first thickness T1 and the second thickness T2. In other words, each of the first thickness T1 and the second thickness T2 may be greater than the third thickness T3.

According to the inventive concepts, the protective pattern PTL may include the first portion PO1 directly contacting the uppermost one of the first and second semiconductor patterns SP1 and SP2 and the second portion PO2 extending from the first portion PO1 along the inner sidewall of the gate spacer GS in the vertical direction D3. The first portion PO1 may have the first thickness T1, and the second portion PO2 may have the second thickness T2. The first thickness T1 may be greater than the second thickness T2. As a result, distances between a gate electrode GE and the first and second semiconductor patterns SP1 and SP2 may increase. Accordingly, current leaking from the first and second semiconductor patterns SP1 and SP2 to the gate electrode GE may be reduced. For the above-described reasons, the electrical properties and reliability of the semiconductor device 7 may improve.

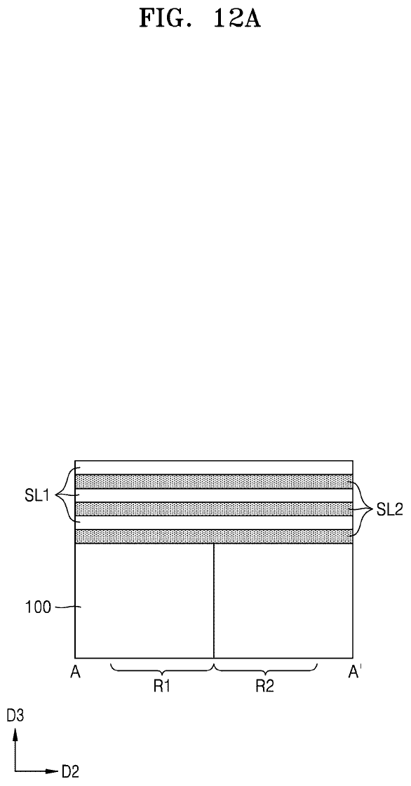

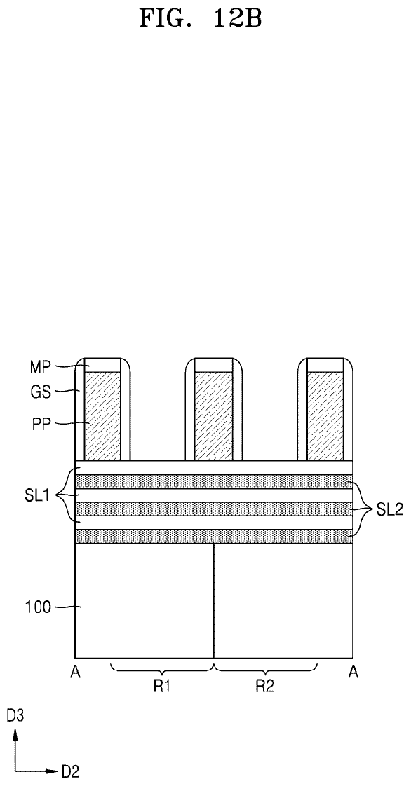

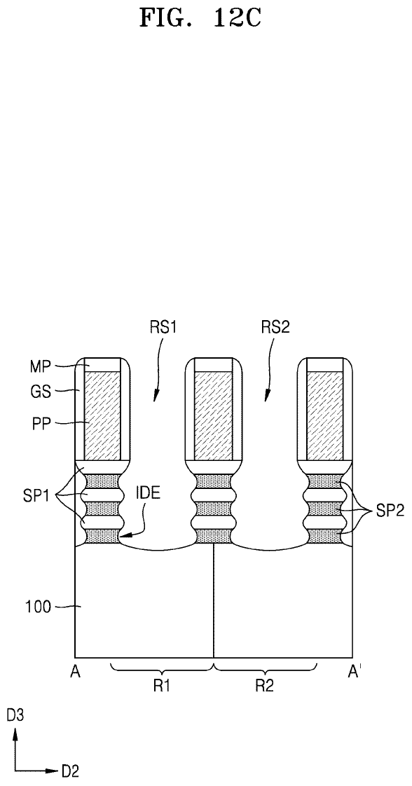

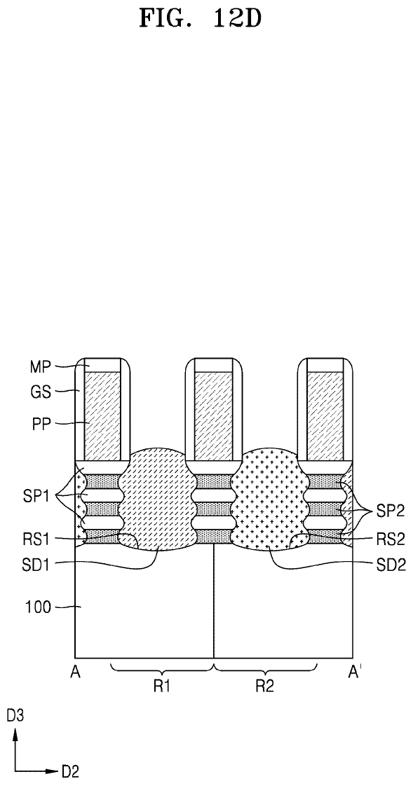

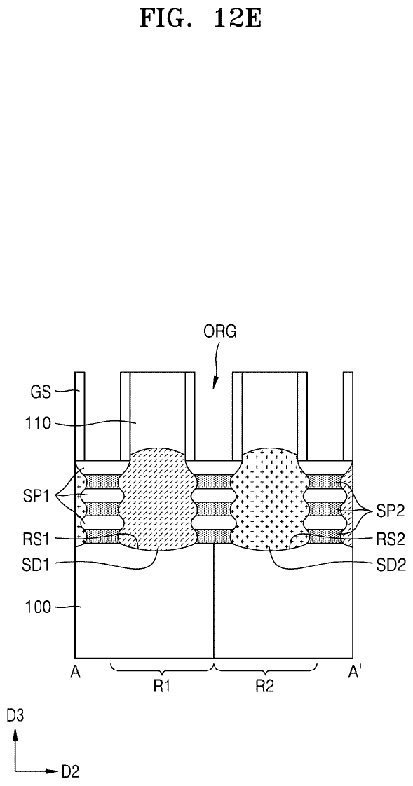

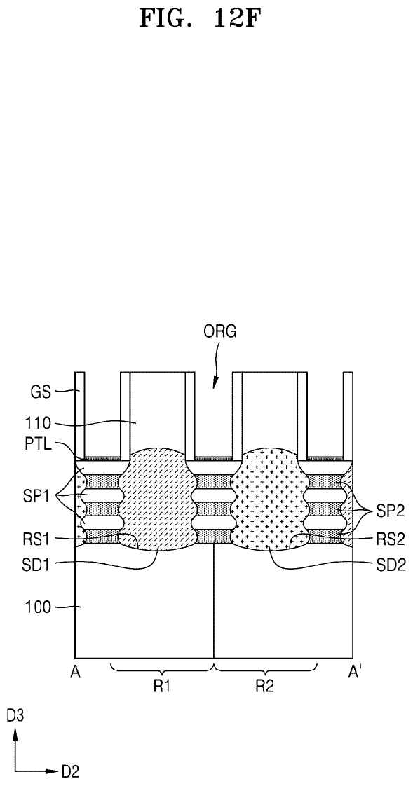

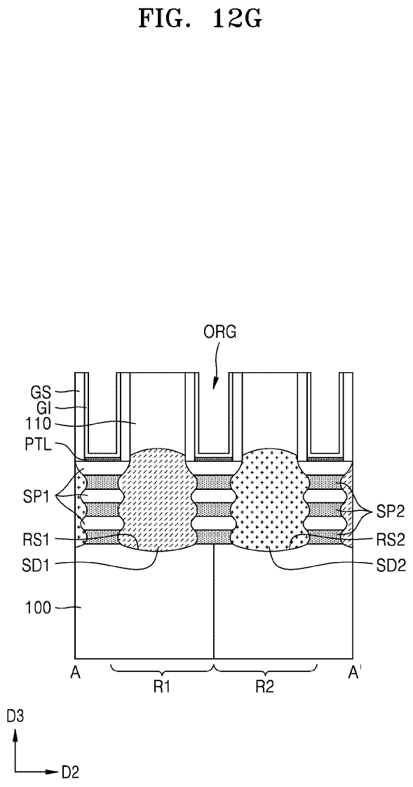

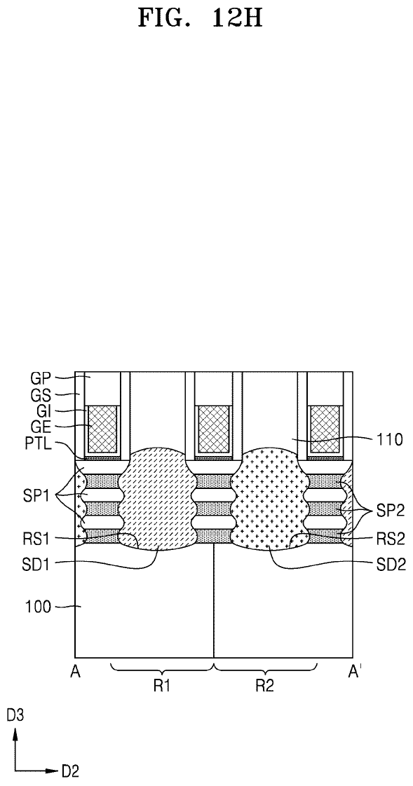

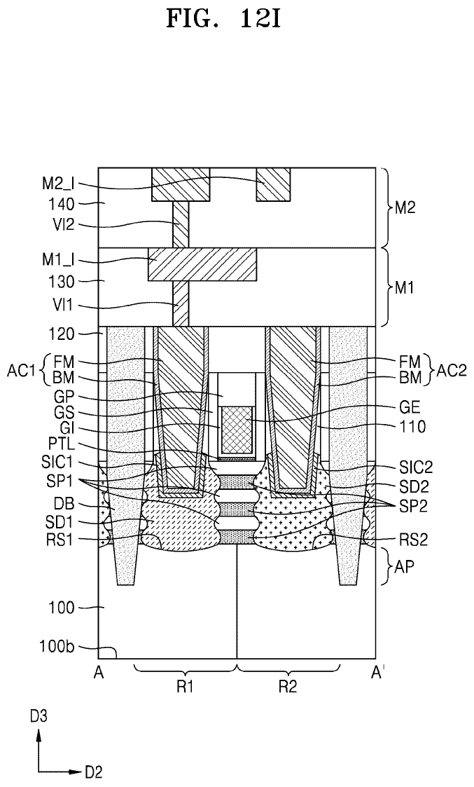

FIGS. 12A to 12I are cross-sectional views illustrating a method of manufacturing a semiconductor device, according to some embodiments. Specifically, FIGS. 12A to 12I are cross-sectional views taken along line A-A′ of FIG. 1, illustrating a method of manufacturing the semiconductor device 1 shown in FIG. 2.

Referring to FIGS. 1 and 12A, a substrate 100 including an active region AR may be provided. In the active region AR, the substrate 100 may include a first region R1 and a second region R2.

The first region R1 of the substrate 100 may be doped with impurities of a first conductivity type, and the second region R2 of the substrate 100 may be doped with impurities of a second conductivity type. The first conductivity type may be different from the second conductivity type. For example, the first region R1 of the substrate 100 may have the first conductivity type, and the second region R2 of the substrate 100 may have the second conductivity type.

First semiconductor layers SL1 and second semiconductor layers SL2 may be alternately stacked one-by-one on the substrate 100. The first semiconductor layers SL1 may include one of silicon, germanium, or silicon-germanium, and the second semiconductor layers SL2 may include another one of silicon, germanium, or silicon-germanium.

The second semiconductor layers SL2 may include a material having etch selectivity with respect to the first semiconductor layers SL1. For example, the first semiconductor layers SL1 may include silicon, and the second semiconductor layers SL2 may include silicon-germanium. Each of the second semiconductor layers SL2 may have a germanium (Ge) concentration of about 10 at % to about 30 at %.

The first semiconductor layers SL1 and the second semiconductor layers SL2 may be formed by using a chemical vapor deposition (CVD) process, a physical vapor deposition (PVD) process, an atomic layer deposition (ALD) process, and/or a combination thereof.

Although not shown, mask patterns may be respectively formed on active regions AR of the substrate 100. The mask pattern may have a line shape or bar shape extending in the second lateral direction D2.

A trench (not shown) may be formed by performing a patterning process using the mask patterns as etch masks. Due to the trench, an upper portion of the substrate 100 may have a structure protruding in a vertical direction D3.

Referring to FIGS. 1 and 12B, sacrificial patterns PP may be formed on the substrate 100 and intersect with the first and second semiconductor layers SL1 and SL2. Each of the sacrificial patterns PP may be formed in a line shape or bar shape extending in a first lateral direction D1. The sacrificial patterns PP may be arranged in the second lateral direction D2. The sacrificial patterns PP may be formed on an uppermost one of the first and second semiconductor layers SL1 and SL2.

Specifically, the formation of the sacrificial patterns PP may include forming a sacrificial film on an entire surface of the substrate 100, forming hard mask patterns MP on the sacrificial film, and patterning the sacrificial film by using the hard mask patterns MP as an etch mask. The sacrificial film may include polysilicon. Accordingly, each of the sacrificial patterns PP may include polysilicon.

A pair of gate spacers GS may be formed on both (i.e., opposing) sidewalls of each of the sacrificial patterns PP. The formation of the gate spacers GS may include conformally forming a gate spacer film on the entire surface of the substrate 100 and anisotropically etching the gate spacer film. In some embodiments, the gate spacer GS may include a multilayered film including at least two films.

Referring to FIGS. 1, 12B and 12C, a first recess RS1 and a second recess RS2 may be formed in the first and second semiconductor layers SL1 and SL2. The first recess RS1 may vertically overlap the first region R1 of the substrate 100. The second recess RS2 may vertically overlap the second region R2 of the substrate 100. Due to the first recess RS1, a portion of the first region R1 of the substrate 100 may be removed. Due to the second recess RS2, a portion of the second region R2 of the substrate 100 may be removed.

Specifically, the first and second semiconductor layers SL1 and SL2 may be etched by using the hard mask patterns MP and the gate spacers GS as etch masks, and thus, the first recess RS1 and the second recess RS2 may be formed.

The formation of the first recess RS1 and the second recess RS2 may further include performing a selective etching process on the second semiconductor layers SL2, which are exposed. Due to the selective etching process, each of the second semiconductor layers SL2 may be indented to form an indent region IDE. Thus, each of the first recess RS1 and the second recess RS2 may have an inner sidewall with a wavy shape.

During the formation of the first recess RS1 and the second recess RS2, first and second semiconductor patterns SP1 and SP2 may be alternately stacked one-by-one between the first recess RS1 and the second recess RS2.

Referring to FIGS. 1 and 12D, a first source/drain pattern SD1 may be formed inside the first recess RS1. Specifically, an SEG process may be performed by using the inner sidewall of the first recess RS1 as a seed layer, and thus, the first source/drain pattern SD1 may be formed. The first source/drain pattern SD1 may be grown by using, as seeds, first and second semiconductor patterns SP1 and SP2, which are exposed by the first recess RS1, and the substrate 100.

In some embodiments, the SEG process may include a CVD process or a molecular beam epitaxy (MBE) process.

In some embodiments, during the formation of the first source/drain pattern SD1, impurities (e.g., phosphorus (P), arsenic (As), or antimony (Sb)) may be implanted in-situ into the first source/drain pattern SD1 such that the first source/drain pattern SD1 exhibits the first conductivity type. In other embodiments, after the first source/drain pattern SD1 is formed, impurities may be implanted into the first source/drain pattern SD1.

A second source/drain pattern SD2 may be formed inside the second recess RS2. Specifically, an SEG process may be performed by using the inner sidewall of the second recess RS2 as a seed layer, and thus, the second source/drain pattern SD2 may be formed.

In some embodiments, during the formation of the second source/drain pattern SD2, impurities (e.g., boron (B), gallium (Ga), or indium (In)) may be implanted in-situ into the second source/drain pattern SD2 such that the second source/drain pattern SD2 exhibits the second conductivity type. In other embodiments, after the second source/drain pattern SD2 is formed, impurities may be implanted into the second source/drain pattern SD2.

Referring to FIGS. 1 and 12E, a first interlayer insulating film 110 may be formed to be on (e.g., to cover) the first and second source/drain patterns SD1 and SD2, the hard mask patterns MP, and the gate spacers GS. In some embodiments, the first interlayer insulating film 110 may include a silicon oxide film.

The first interlayer insulating film 110 may be planarized so that upper surfaces of the sacrificial patterns PP may be exposed. The planarization of the first interlayer insulating film 110 may be performed by using an etchback process or a chemical mechanical polishing (CMP) process. During the planarization process, the hard mask patterns MP may be entirely removed. As a result, an upper surface of the first interlayer insulating film 110 may form a planar surface with the upper surfaces of the sacrificial patterns PP and upper surfaces of the gate spacers GS.

The sacrificial patterns PP, which are exposed, may be selectively removed. By removing the sacrificial patterns PP, outer regions ORG exposing the first and second semiconductor patterns SP1 and SP2 may be formed. The removal of the sacrificial patterns PP may include performing a wet etching process using an etchant for selectively etching polysilicon.

Referring to FIGS. 1 and 12F, a protective pattern PTL may be formed to be on (e.g., to cover) an upper surface of an uppermost one of the first and second semiconductor patterns SP1 and SP2. The protective pattern PTL may extend in the first lateral direction D1 as shown in FIG. 4. As shown in FIG. 4, the protective pattern PTL may be on (e.g., may cover) sidewalls of the first and second semiconductor patterns SP1 and SP2 in the first lateral direction D1. The protective pattern PTL may entirely cover surfaces of the first and second semiconductor patterns SP1 and SP2, which are exposed to the outside.

The protective pattern PTL may include a low-k dielectric material. For example, the protective pattern PTL may include a silicon oxide film.

According to the inventive concepts, the protective pattern PTL may be on (e.g., may cover) the sidewalls of the first and second semiconductor patterns SP1 and SP2 in the first lateral direction D1. That is, the protective pattern PTL may entirely cover the surfaces of the first and second semiconductor patterns SP1 and SP2, which are exposed to the outside. Accordingly, even when a wet etching process having etch selectivity with respect to the second semiconductor patterns SP2 is performed later, the second semiconductor patterns SP2 may not be removed.

Referring to FIGS. 1, 3, 4, and 12G, a gate insulating film GI may be formed on the protective pattern PTL. The gate insulating film GI may include an interfacial film IL and a high-k dielectric film HK. After the interfacial film IL is formed first, the high-k dielectric film HK may be formed.

The interfacial film IL may be on (e.g., may cover) the protective pattern PTL. Specifically, the interfacial film IL may be directly on (e.g., may directly cover) an upper surface of the protective pattern PTL and a sidewall of the protective pattern PTL in the first lateral direction D1.

The high-k dielectric film HK may be formed on the interfacial film IL. The high-k dielectric film HK may be directly on (e.g., may directly cover) an upper surface of the interfacial film IL and a sidewall of the gate spacer GS.

Referring to FIGS. 1 and 12H, a gate electrode GE may be formed on the gate insulating film GI. The gate electrode GE may be formed in the outer region ORG. The gate electrode GE may be removed, and thus, a height of the gate electrode GE may be reduced. A gate capping pattern GP may be formed on the gate electrode GE, which is recessed.

Referring to FIGS. 1 and 12I, a second interlayer insulating film 120 may be formed on the first interlayer insulating film 110. The second interlayer insulating film 120 may include a silicon oxide film.

A first active contact AC1 may be formed to pass through the second interlayer insulating film 120 and the first interlayer insulating film 110 and may be electrically connected to the first source/drain pattern SD1. A second active contact AC2 may be formed to pass through the second interlayer insulating film 120 and the first interlayer insulating film 110 and may be electrically connected to the second source/drain pattern SD2.

The formation of the first and second active contacts AC1 and AC2 may include forming a barrier pattern BM and forming a conductive pattern FM on the barrier pattern BM. The barrier pattern BM may be conformally formed and may include a metal film/metal nitride film. The conductive pattern FM may include a low-resistance metal.

Before the first active contact AC1 is formed, a first metal-semiconductor compound layer SIC1 may be formed on the first source/drain pattern SD1. Before the second active contact AC2 is formed, a second metal-semiconductor compound layer SIC2 may be formed on the second source/drain pattern SD2.

The first metal-semiconductor compound layer SIC1 may be formed between the first source/drain pattern SD1 and the first active contact AC. The second metal-semiconductor compound layer SIC2 may be formed between the second source/drain pattern SD2 and the second active contact AC2.

Isolation structures DB may each be formed apart from the first and second source/drain patterns SD1 and SD2 in the second lateral direction D2. A pair of isolation structures DB may be spaced apart each other in the second lateral direction D2 with the first and second source/drain patterns SD1 and SD2 therebetween. The isolation structure DB may extend from the second interlayer insulating film 120 through the first interlayer insulating film 110 into the substrate 100. The isolation structure DB may include an insulating material, such as a silicon oxide film or a silicon nitride film.

A third interlayer insulating film 130 may be formed on the first and second active contacts AC1 and AC2 and the isolation structures DB. A first metal layer M1 may be formed in the third interlayer insulating film 130. A fourth interlayer insulating film 140 may be formed on the third interlayer insulating film 130. A second metal layer M2 may be formed in the fourth interlayer insulating film 140.

Referring back to FIGS. 1 and 2, a planarization process may be performed on a bottom surface 100b of the substrate 100 of FIG. 12I. As a result, a thickness of the substrate 100 in the vertical direction D3 may be reduced.

Subsequently, a lower wiring layer 200 may be formed under the substrate 100. The lower wiring layer 200 may include a lower insulating layer 202 and a lower wiring 204. The lower wiring layer 200 may be formed using a damascene process. As a result, the semiconductor device 1 shown in FIG. 2 may be manufactured.

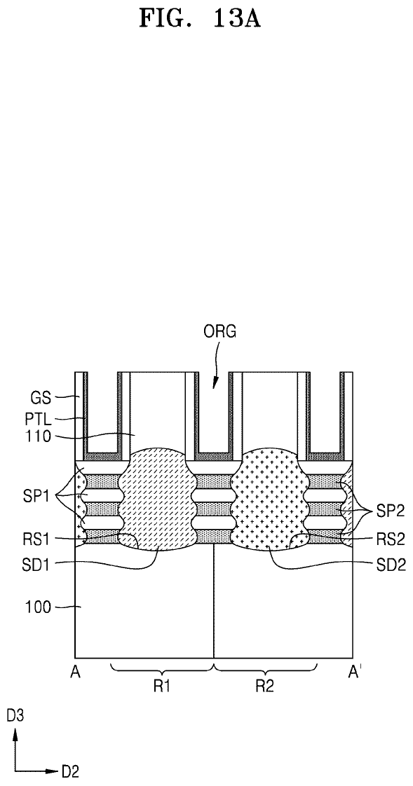

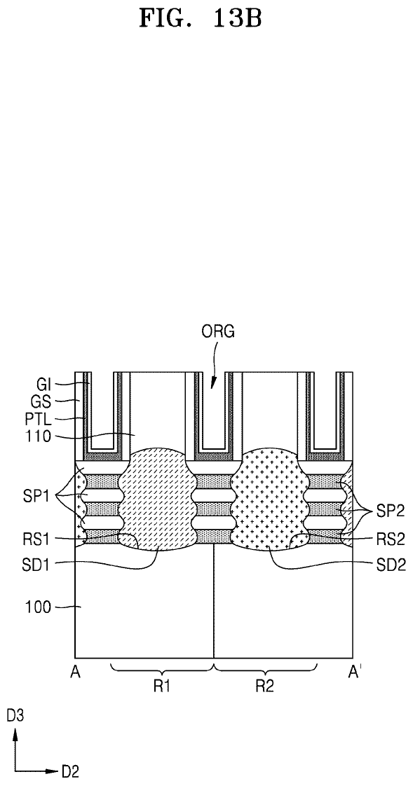

FIGS. 13A and 13B are cross-sectional views of a method of manufacturing a semiconductor device, according to some embodiments. Specifically, FIGS. 13A and 13B illustrate a method of manufacturing the semiconductor device 7 shown in FIGS. 10 and 11.

Referring to FIGS. 1 and 13A, after the manufacturing method described with reference to FIGS. 12A to 12F is performed, a deposition process may be performed, and thus, a thickness of a protective pattern PTL may increase.

Referring to FIGS. 1 and 13A together with FIG. 11, the protective pattern PTL may include a first portion PO1 and a second portion PO2 due to a deposition process. The first portion PO1 may be a portion that is in direct contact with an uppermost one of the first and second semiconductor patterns SP1 and SP2. The second portion PO2 may be a portion extending from the first portion PO1 along an inner surface of the gate spacer GS in a vertical direction D3. The first portion PO1 may have a first thickness T1. The second portion PO2 may have a second thickness T2. The first thickness T1 may be greater than the second thickness T2.

Referring to FIGS. 1 and 13B, a gate insulating film GI may be formed on the protective pattern PTL.

Referring to FIGS. 1 and 13B together with FIGS. 4, 10, and 11, the gate insulating film GI may include an interfacial film IL and a high-k dielectric film HK. The interfacial film IL may be on (e.g., may cover) an upper surface of the first portion PO1 and a sidewall of the first portion PO1 in the first lateral direction D1. For example, the interfacial film IL may be on an upper surface of the first portion PO1 and may be on opposing sidewalls of the first portion PO1 in the first lateral direction D1.

The high-k dielectric film HK may be on (e.g., may cover) an upper surface of the interfacial film IL. The high-k dielectric film HK may be on (e.g., may cover) an inner sidewall of the second portion PO2 of the protective pattern PTL.

Subsequently, the manufacturing method described with reference to FIGS. 12H and 12I may be wholly performed. As a result, the semiconductor device 7 shown in FIGS. 10 and 11 may be manufactured.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Example embodiments are described herein with reference to the accompanying drawings. Many different forms and embodiments are possible without deviating from the teachings of the present disclosure. Accordingly, the present disclosure should not be construed as limited to the example embodiments set forth herein.

While the inventive concepts have been particularly shown and described with reference to example embodiments thereof, it will be understood that various changes in form and details may be made therein without departing from the scope of the following claims.

What is claimed is:

1. A semiconductor device comprising:
a substrate comprising a first region and a second region beside the first region, the first region having a first conductivity type and the second region having a second conductivity type different from the first conductivity type;
first semiconductor patterns and second semiconductor patterns alternately stacked one-by-one on an upper surface of the substrate, the first semiconductor patterns comprising a different material from the second semiconductor patterns;
a gate electrode on an uppermost one of the first and second semiconductor patterns, the gate electrode extending in a first lateral direction;
a first source/drain pattern and a second source/drain pattern spaced apart from each other, with the first and second semiconductor patterns therebetween, in a second lateral direction intersecting the first lateral direction, the first source/drain pattern having the first conductivity type and the second source/drain pattern having the second conductivity type; and
a protective pattern between the gate electrode and the uppermost one of the first and second semiconductor patterns, the protective pattern comprising a dielectric material,
wherein the protective pattern is directly on sidewalls of the first and second semiconductor patterns in the first lateral direction.

2. The semiconductor device of claim 1, further comprising a gate insulating film between the gate electrode and the protective pattern,
wherein the gate insulating film is directly on an upper surface of the protective pattern and is directly on a sidewall of the protective pattern in the first lateral direction.

3. The semiconductor device of claim 2, wherein the gate insulating film comprises an interfacial film in contact with the protective pattern and a high-k dielectric film in contact with the gate electrode, and
wherein the high-k dielectric film is spaced apart from the protective pattern, with the interfacial film therebetween, in a vertical direction.

4. The semiconductor device of claim 1, wherein the protective pattern comprises silicon oxide, silicon oxynitride, or a combination thereof.

5. The semiconductor device of claim 1, further comprising a gate spacer on a sidewall of the gate electrode in the second lateral direction,
wherein the protective pattern does not overlap the gate spacer in a vertical direction.

6. The semiconductor device of claim 1, further comprising:
a first active contact electrically connected to the first source/drain pattern and a second active contact electrically connected to the second source/drain pattern; and
a lower wiring layer under the substrate,
wherein the lower wiring layer comprises a lower insulating layer and a lower wiring in the lower insulating layer.

7. The semiconductor device of claim 6, wherein the first active contact and the second active contact extend in a vertical direction, and
wherein the semiconductor device further comprises a metal layer on the first active contact and the second active contact and electrically connected to the first active contact and the second active contact.

8. The semiconductor device of claim 1, further comprising:
a lower wiring layer under the substrate, the lower wiring layer comprising a lower insulating layer and a lower wiring in the lower insulating layer;
a first active contact electrically connected to the first source/drain pattern; and
a second active contact electrically connected to the lower wiring, the second active contact extending through the lower insulating layer and into the second region of the substrate in a vertical direction.

9. The semiconductor device of claim 1, further comprising:
a lower wiring layer under the substrate, the lower wiring layer comprising a lower insulating layer and a lower wiring in the lower insulating layer;
a first active contact electrically connected to the lower wiring, the first active contact extending through the lower insulating layer and into the first region of the substrate in a vertical direction; and
a second active contact electrically connected to the lower wiring, the second active contact extending through the lower insulating layer and into the second region of the substrate in the vertical direction.

10. A semiconductor device comprising:
a lower wiring layer comprising a lower insulating layer and a lower wiring in the lower insulating layer;
first semiconductor patterns and second semiconductor patterns alternately stacked one-by-one on an upper surface of the lower wiring layer, the first semiconductor patterns comprising a different material from the second semiconductor patterns;
a gate electrode on an uppermost one of the first and second semiconductor patterns, the gate electrode extending in a first lateral direction;
a first source/drain pattern and a second source/drain pattern spaced apart from each other, with the first and second semiconductor patterns therebetween, in a second lateral direction intersecting the first lateral direction, the first source/drain pattern having a first conductivity type and the second source/drain pattern having a second conductivity type different from the first conductivity type;
a protective pattern between the gate electrode and the uppermost one of the first and second semiconductor patterns, the protective pattern comprising a dielectric material; and
a gate spacer on a sidewall of the gate electrode in the second lateral direction,
wherein the protective pattern comprises a first portion on the uppermost one of the first and second semiconductor patterns and a second portion extending along an inner sidewall of the gate spacer in a vertical direction.

11. The semiconductor device of claim 10, further comprising a gate insulating film between the gate electrode and the protective pattern,
wherein the gate insulating film comprises an interfacial film directly on the first portion of the protective pattern and a high-k dielectric film directly on an inner sidewall of the second portion of the protective pattern.

12. The semiconductor device of claim 10, further comprising a gate insulating film between the gate electrode and the protective pattern,
wherein the gate insulating film is spaced apart from the gate spacer, with the second portion of the protective pattern therebetween, in the second lateral direction.

13. The semiconductor device of claim 10, wherein a thickness of the first portion of the protective pattern is greater than a thickness of the second portion of the protective pattern.

14. The semiconductor device of claim 10, further comprising a gate insulating film between the gate electrode and the protective pattern,
wherein a portion of the gate insulating film is in contact with the first portion of the protective pattern, and
wherein a thickness of the portion of the gate insulating film is less than each of a thickness of the first portion of the protective pattern and a thickness of the second portion of the protective pattern.

15. The semiconductor device of claim 10, wherein the lower insulating layer is in contact with the first and second source/drain patterns, and
wherein the semiconductor device further comprises a first active contact electrically connected to the lower wiring, the first active contact extending through the lower insulating layer and into the first source/drain pattern in the vertical direction.

16. The semiconductor device of claim 15, further comprising a second active contact electrically connected to the lower wiring, the second active contact extending through the lower insulating layer and into the second source/drain pattern in the vertical direction.

17. The semiconductor device of claim 10, wherein the lower insulating layer is in contact with the first and second source/drain patterns, and
wherein the semiconductor device further comprises:
a first active contact electrically connected to the first source/drain pattern and a second active contact electrically connected to the second source/drain pattern, the first active contact and the second active contact extending in the vertical direction; and
a metal layer on the first active contact and the second active contact and electrically connected to the first active contact and the second active contact.

18. A semiconductor device comprising:
a substrate comprising a first region and a second region beside the first region, the first region having a first conductivity type and the second region having a second conductivity type different from the first conductivity type;
first semiconductor patterns and second semiconductor patterns alternately stacked one-by-one on an upper surface of the substrate, the first semiconductor patterns comprising a different material from the second semiconductor patterns;
a gate electrode on an uppermost one of the first and second semiconductor patterns, the gate electrode extending in a first lateral direction;
a gate spacer on a sidewall of the gate electrode in a second lateral direction intersecting the first lateral direction;
a first source/drain pattern and a second source/drain pattern spaced apart from each other, with the first and second semiconductor patterns therebetween, in the second lateral direction;
a protective pattern between the gate electrode and the uppermost one of the first and second semiconductor patterns, the protective pattern comprising a dielectric material;
a gate capping pattern on an upper surface of the gate electrode;
an interlayer insulating film on the gate capping pattern; and
a metal layer on the interlayer insulating film,
wherein the protective pattern is directly on sidewalls of the first and second semiconductor patterns in the first lateral direction.

19. The semiconductor device of claim 18, further comprising a gate insulating film between the protective pattern and the gate electrode,
wherein the gate insulating film is spaced apart from the gate spacer, with the protective pattern therebetween, in the second lateral direction.

20. The semiconductor device of claim 18, wherein the protective pattern comprises a first portion in contact with the uppermost one of the first and second semiconductor patterns and a second portion extending from the first portion along an inner sidewall of the gate spacer in a vertical direction, and
wherein a thickness of the first portion of the protective pattern is greater than a thickness of the second portion of the protective pattern.
